(19) United States
(12) Patent Application Publication
(10) Pub. No.: US 2020/0220013 A1
(43) Pub. Date: Jul. 9, 2020

(54) SEMICONDUCTOR STRUCTURE AND METHOD OF FORMING THEREOF

(71) Applicant: XIA TAI XIN SEMICONDUCTOR (QING DAO) LTD., Qingdao (CN)

(72) Inventors: KYEONGILL YOON, Singapore (SG); YONGCHUL OH, Singapore (SG)

(21) Appl. No.: 16/679,336

(22) Filed: Nov. 11, 2019

Related U.S. Application Data
(60) Provisional application No. 62/781,666, filed on Dec. 19, 2018.

(51) Int. Cl. H01L 29/78; H01L 29/66

(52) U.S. Cl. CPC H01L 29/7835; H01L 29/6653; H01L 29/6659; H01L 29/66659

(57) ABSTRACT

A semiconductor structure is disclosed. The semiconductor structure includes a first source/drain region and a second source/drain region formed below the top surface of the substrate and a gate structure disposed between the first source/drain region and the second source/drain region. The first source/drain region are formed to have a size greater than a size of the second source/drain region.

### CROSS-REFERENCES TO RELATED APPLICATIONS

This application claims the benefit of U.S. Provisional Patent Application No. 62/781,666 filed on Dec. 19, 2018, which is hereby incorporated by reference herein and made a part of specification.

### BACKGROUND

### 1. Field

The present disclosure generally relates to semiconductor structure, and more particularly, semiconductor structure having asymmetric doped regions to reduce current mismatch and improve reliability.

### 2. Description of the Related Art

A DRAM device includes an array of memory cells. Each of the memory cells includes a transistor and a capacitor coupled to the transistor. The capacitor stores information based on the presence or absence of a charge in the capacitive element. As the degree of integration of DRAM devices increases, dimensions of each memory cell are reduced, which may lead to undesired transistor degradation.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a flowchart of a method of forming a semiconductor structure according to some embodiments of the instant disclosure;

FIG. 2A-2C illustrates a cross section of a semiconductor structure according to some embodiments of the instant disclosure;

FIG. 3 illustrates a cross section of a semiconductor structure according to some embodiments of the instant disclosure;

FIG. 4 illustrates a flowchart of a method of forming a semiconductor structure according to some embodiments of the instant disclosure;

FIG. 5A-5C illustrates a cross section of a semiconductor structure according to some embodiments of the instant disclosure; and

FIG. 6 illustrates a cross section of a semiconductor structure according to some embodiments of the instant disclosure.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

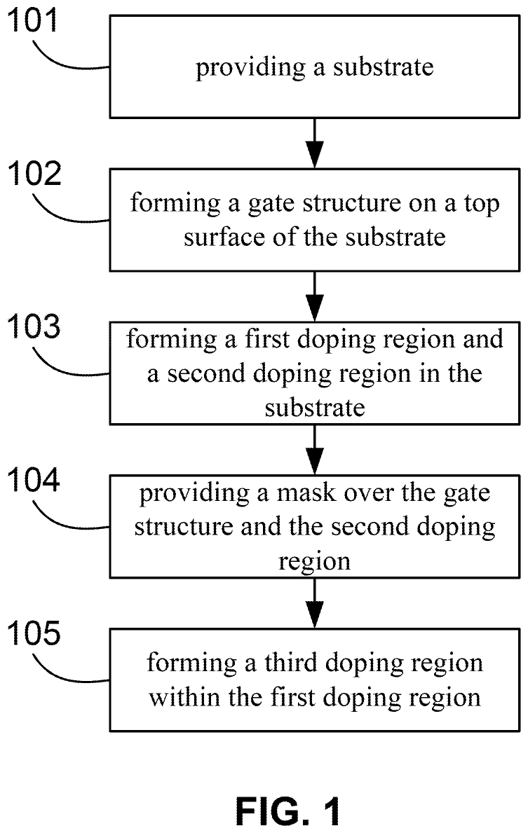

FIG. 1 illustrates a flowchart of a method of forming a semiconductor structure according to some embodiments of the instant disclosure. The method includes providing a substrate (101), forming a gate structure on a top surface of the substrate (102), forming a first doping region and a second doping region in the substrate (103), providing a mask over the gate structure and the second doping region (104), and forming a third doping region within the first doping region and extending away from a bottom surface of the first doping region (105).

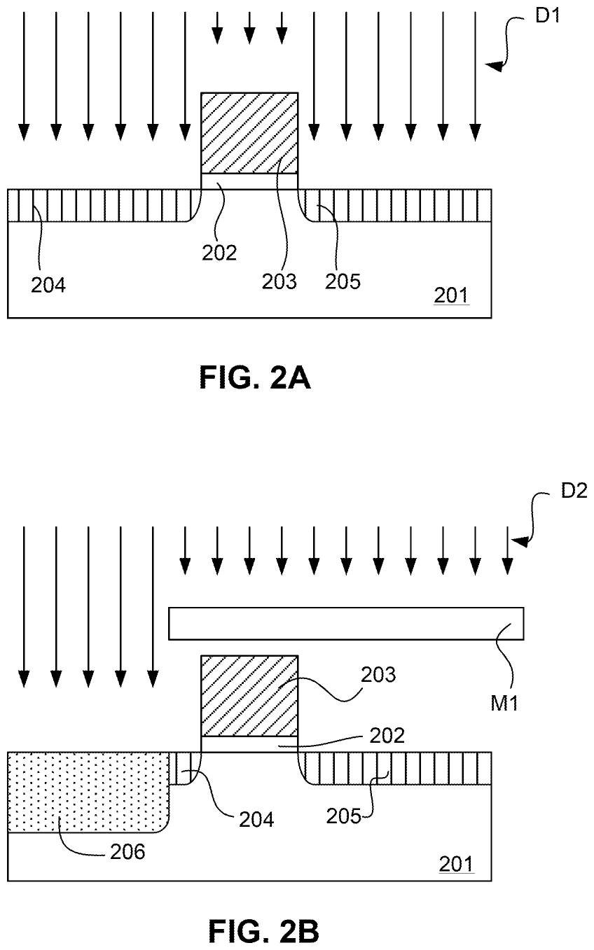

FIG. 2A-2C illustrates a cross section of a semiconductor structure according to some embodiments of the instant disclosure. In FIG. 2A, a substrate 201 is provided. A gate structure including an oxide layer 202 and a gate electrode 203 is formed on the top surface of the substrate 201. The substrate 201 is bombarded with dopants in the direction shown by arrows D1. The dopants may be N-type dopants or P-type dopants. The first doping region 204 and the second doping region 205 is formed underneath the top surface of the substrate 201. In some embodiments, the gate structure is disposed between the first doping region 204 and the second doping region 205.

In FIG. 2B, a mask M1 is provided over the gate structure and the second doping region 205. A third doping region 206 is formed within the first doping region 204 and further extending away from a bottom surface of the first doping region 204. In some embodiments, a width of the first doping region 204 is the same as the width of the third doping region 206. In some embodiments, a width of the first doping region 204 is greater than the width of the third doping region 206. The width of the third doping region 206 depend on the area of the first doping region 204 exposed by the opening of the mask M1. The substrate 201 is bombarded with dopants in the direction shown by arrows D2 to form the third doping region 206. The dopants may be N-type dopants or P-type dopants.

In some embodiments, the method further includes forming a first spacer 207 and a second spacer 208 on corresponding sidewalls of the gate structure. In FIG. 2C, the first spacer 207 and the second spacer 208 have the same width.

In some embodiments, the source region of semiconductor structure comprises the first doping region 204 and the third doping region 206. In some embodiments, the drain region of semiconductor structure comprises the second doping region 205.

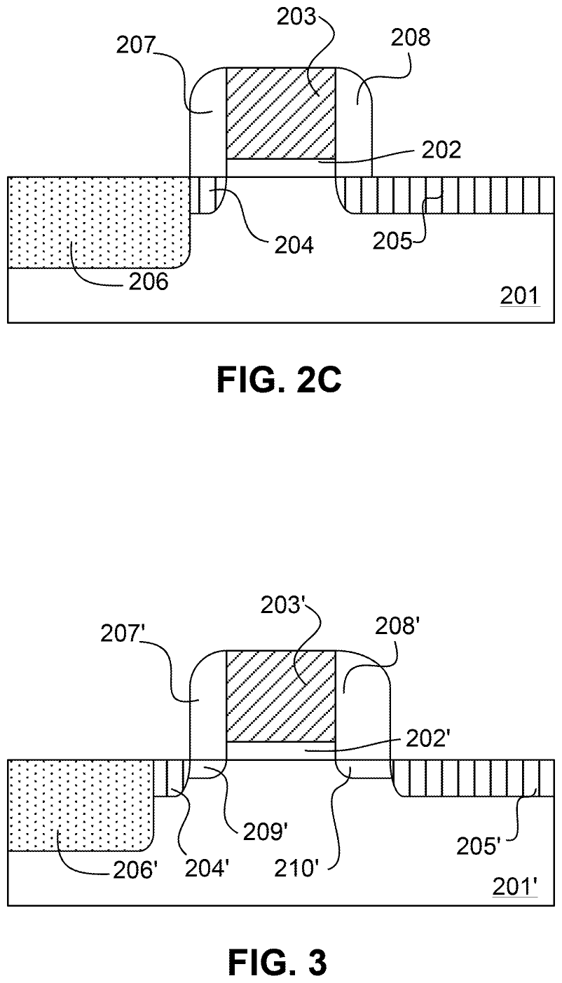

In some embodiments, the method further includes forming a first lightly doped region 209′ and a second lightly doped region 210′ in the substrate 201′. As shown in FIG. 3, in some embodiments, a width of the first spacer 207′ is less than a width of the second spacer 208′. A width of the first lightly doped region 209′ is less than a width of the second lightly doped region 210′. In some embodiments, the width of the first lightly doped region 209′ is greater than a width of the first doping region 204′. The width of the second lightly doped region 209′ is greater than a width of the second doping region 205′.

In some embodiments, the source region of semiconductor structure comprises the first lightly doped region 209′, the first doping region 204′, and the third doping region 206′. In some embodiments, the drain region of semiconductor structure comprises the second lightly doped region 210′ and the second doping region 205′.

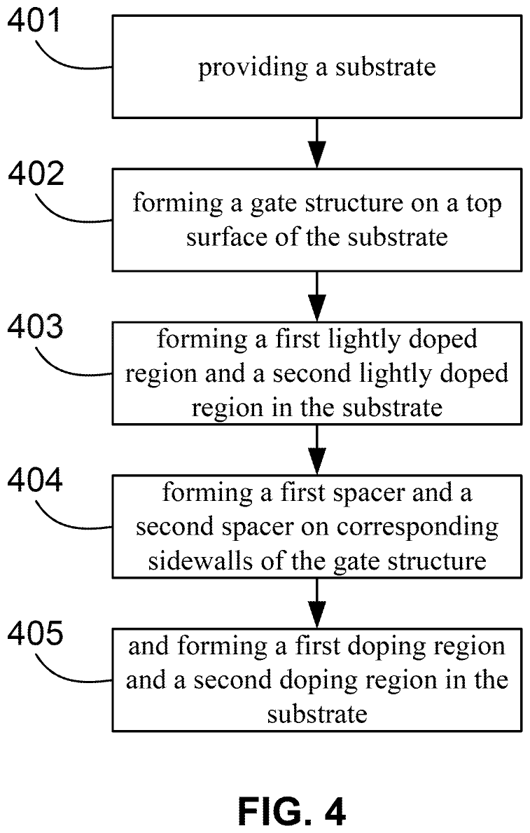

FIG. 4 illustrates a flowchart of a method of forming a semiconductor structure according to some embodiments of the instant disclosure. The method includes providing a substrate (401), forming a gate structure on a top surface of the substrate (402), forming a first lightly doped region and a second lightly doped region in the substrate (403), forming a first spacer and a second spacer on corresponding sidewalls of the gate structure (404), and forming a first doping region and a second doping region in the substrate (405). A width of the first lightly doped region is less than a width of the second lightly doped region. The gate structure is disposed between the first doping region and the second doping region.

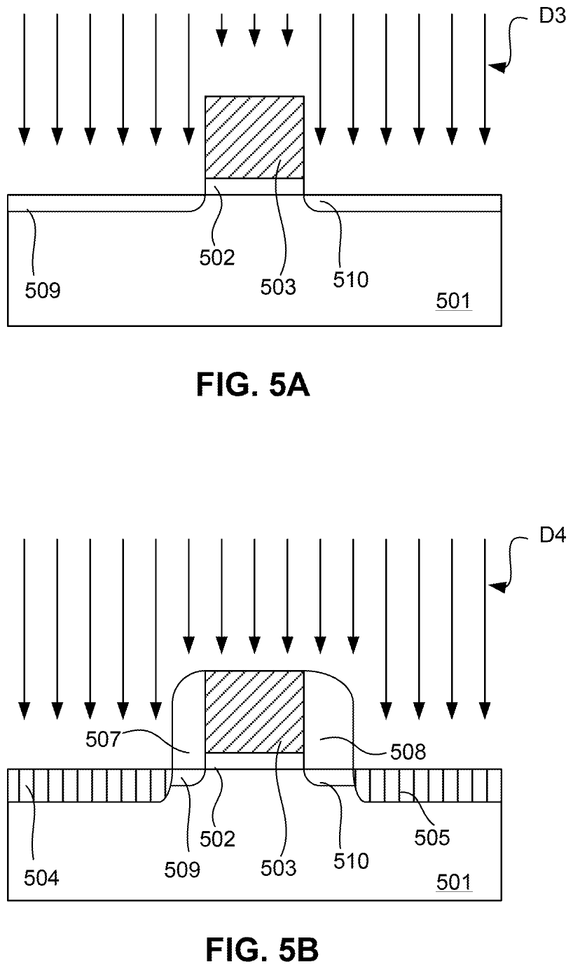

FIG. 5A-5C illustrates a cross section of a semiconductor structure according to some embodiments of the instant disclosure. In FIG. 5A, a substrate 501 is provided. A gate structure including an oxide layer 502 and a gate electrode 503 is formed on the top surface of the substrate 501. The substrate 501 is bombarded with dopants in the direction shown by arrows D3. The dopants may be N-type dopants or P-type dopants. The first lightly doped region 509 and the second lightly doped region 510 is formed underneath the top surface of the substrate 501. In some embodiments, the gate structure is disposed between the first lightly doped region 509 and the second lightly doped region 510.

In FIG. 5B, the first spacer 507 and the second spacer 508 are formed on corresponding sidewalls of the gate structure. In some embodiments, a width of the first spacer 507 is less than a width of the second spacer 508.

Afterwards, the substrate 501 is bombarded with dopants in the direction shown by arrows D4. The dopants may be N-type dopants or P-type dopants. The first doping region 504 and the second doping region 505 is formed underneath the top surface of the substrate 501. In some embodiments, the gate structure is disposed between the first doping region 504 and the second doping region 505.

In some embodiments, the second doping region 505 has a height greater than a height of the first lightly doped region 510 as shown in FIG. 5B. In some embodiments, the first doping region 504′ has a same height as the first lightly doped region 509′ as shown in FIG. 5C.

In some embodiments, the source region of semiconductor structure comprises the first lightly doped region 509′ and the first doping region 504′. In some embodiments, the drain region of semiconductor structure comprises the second lightly doped region 510′ and the second doping region 505′.

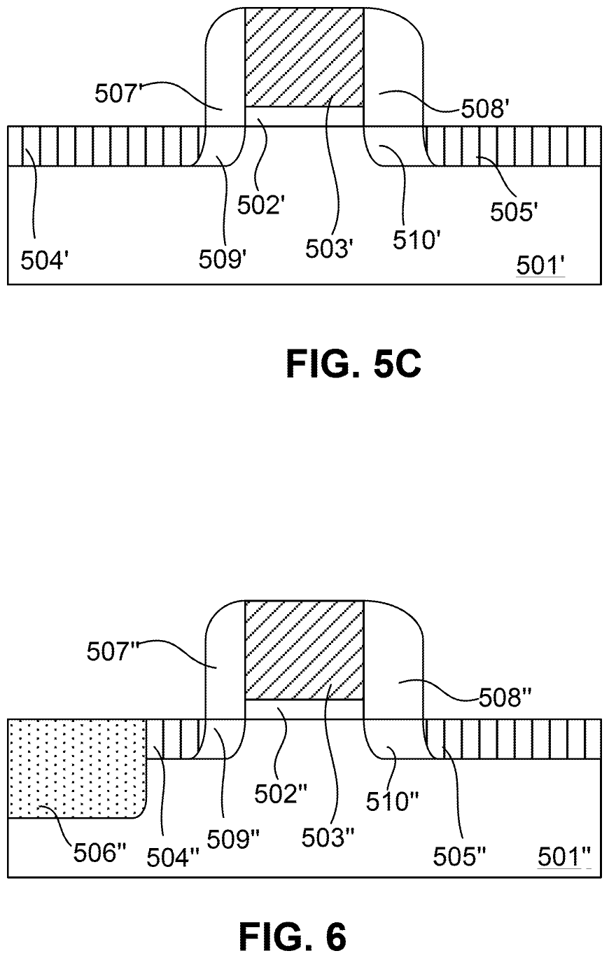

As shown in FIG. 6, in some embodiments, the method further comprises providing a mask over the gate structure, and the second doping region 505″, and forming a third doping region 506″ within the first doping region 504″ and extending away from a bottom surface of the first doping region 504″. In some embodiments, a width of the first doping region 504″ is same as the width of the third doping region 506″ . In some embodiments, a width of the first doping region 504″ is greater than the width of the third doping region 506″. The width of the third doping region 506″ depend on the area of the first doping region 504″ exposed by the opening of the mask.

In some embodiments, the source region of semiconductor structure comprises the first lightly doped region 509″, the first doping region 504″, and third doping region 506″. In some embodiments, the drain region of semiconductor structure comprises the second lightly doped region 510″ and the second doping region 505″.

In some embodiments, the first source/drain region includes a first doping region and a third doping region, and the second source/drain region includes a second doping region. In some embodiments, a width of the first doping region is greater than the width of the third doping region. In some embodiments, a total volume of the first source/drain region is greater than a total volume of the second source/drain region.

It can be seen in the exemplary embodiments disclosed in FIGS. 1-6, in some embodiments, the first source/drain region includes a first doping region and a first lightly doped region, and the second source/drain region includes a second doping region and a second lightly doped region. In some embodiments, a width of the first lightly doped region is less than a width of the second lightly doped region. In some embodiments, a width of the first lightly doped region is greater than a width of the first doping region and a width of the second lightly doped region is greater than a width of the second doping region. In some embodiments, a total volume of the first source/drain region is greater than a total volume of the second source/drain region. In some embodiments, the first source/drain region further includes a first doping region, a first lightly doped region, and a third doping region formed within the first doping region and extending away from a bottom surface of the first doping region. In some embodiments, a total volume of the first source/drain region is greater than a total volume of the second source/drain region.

Accordingly, one aspect of the instant disclosure provides a method of forming a semiconductor structure that comprises providing a substrate; forming a gate structure on a top surface of the substrate; forming a first doping region and a second doping region in the substrate, wherein the gate structure is disposed between the first doping region and the second doping region; providing a mask over the gate structure and the second doping region; and forming a third doping region within the first doping region and extending away from a bottom surface of the first doping region.

In some embodiments, the method further comprises forming a first spacer and a second spacer on corresponding sidewalls of the gate structure; and forming a first lightly doped region and a second lightly doped region in the substrate. A width of the first lightly doped region is less than a width of the second lightly doped region.

In some embodiments, the width of the first lightly doped region is greater than a width of the first doping region; and wherein the width of the second lightly doped region is greater than a width of the second doping region.

In some embodiments, a width of the first spacer is less than a width of the second spacer.

In some embodiments, a width of the first doping region is greater than the width of the third doping region.

Accordingly, another aspect of the instant disclosure provides a method of forming a semiconductor structure that comprises providing a substrate; forming a gate structure on a top surface of the substrate; forming a first doping region and a second doping region in the substrate, wherein the gate structure is disposed between the first doping region and the second doping region; forming a first spacer and a second spacer on corresponding sidewalls of the gate structure; and forming a first lightly doped region and a second lightly doped region in the substrate. A width of the first lightly doped region is less than a width of the second lightly doped region.

In some embodiments, the width of the first lightly doped region is greater than a width of the first doping region; and wherein the width of the second lightly doped region is greater than a width of the second doping region.

In some embodiments, the method further comprises providing a mask over the gate structure and the second doping region; and forming a third doping region within the first doping region and extending away from a bottom surface of the first doping region.

In some embodiments, a width of the first doping region is greater than the width of the third doping region.

In some embodiments, a width of the first spacer is less than a width of the second spacer.

Accordingly, another aspect of the instant disclosure provides a semiconductor structure that comprises a substrate having a top surface and a bottom surface opposite the top surface; a gate structure disposed on the top surface of the substrate; and a first source/drain region and a second source/drain region formed below the top surface of the substrate. A cross sectional area of the first source/drain region is greater than a cross sectional area of second source/drain region.

In some embodiments, the first source/drain region includes a first doping region and a third doping region, and the second source/drain region includes a second doping region.

In some embodiments, a width of the first doping region is greater than the width of the third doping region.

In some embodiments, the structure further comprises a first spacer and a second spacer corresponding disposed on sidewalls of the gate structure. A width of the first spacer is less than a width of the second spacer.

In some embodiments, the first source/drain region includes a first doping region and a first lightly doped region, and the second source/drain region includes a second doping region and a second lightly doped region.

In some embodiments, a width of the first lightly doped region is less than a width of the second lightly doped region.

In some embodiments, a width of the first lightly doped region is greater than a width of the first doping region; and wherein a width of the second lightly doped region is greater than a width of the second doping region.

In some embodiments, the first source/drain region further includes a third doping region formed within the first doping region and extending away from a bottom surface of the first doping region.

In some embodiments, a total volume of the first source/drain region is greater than a total volume of the second source/drain region.

In some embodiments, the gate structure comprises an oxide layer disposed on the top surface of the substrate; and a gate electrode disposed on the oxide layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a semiconductor structure, comprising:
providing a substrate;
forming a gate structure on a top surface of the substrate;
forming a first doping region and a second doping region in the substrate, wherein the gate structure is disposed between the first doping region and the second doping region;
providing a mask over the gate structure and the second doping region; and
forming a third doping region within the first doping region and extending away from a bottom surface of the first doping region.

2. The method of claim 1, further comprising:
forming a first spacer and a second spacer on corresponding sidewalls of the gate structure; and
forming a first lightly doped region and a second lightly doped region in the substrate;
wherein a width of the first lightly doped region is less than a width of the second lightly doped region.

3. The method of claim 2, wherein the width of the first lightly doped region is greater than a width of the first doping region; and wherein the width of the second lightly doped region is greater than a width of the second doping region.

4. The method of claim 2, wherein a width of the first spacer is less than a width of the second spacer.

5. The method of claim 1, wherein a width of the first doping region is greater than the width of the third doping region.

6. A method of forming a semiconductor structure, comprising:
providing a substrate;
forming a gate structure on a top surface of the substrate;
forming a first doping region and a second doping region in the substrate, wherein the gate structure is disposed between the first doping region and the second doping region;
forming a first spacer and a second spacer on corresponding sidewalls of the gate structure; and
forming a first lightly doped region and a second lightly doped region in the substrate;
wherein a width of the first lightly doped region is less than a width of the second lightly doped region.

7. The method of claim 6, wherein the width of the first lightly doped region is greater than a width of the first doping region; and wherein the width of the second lightly doped region is greater than a width of the second doping region.

8. The method of claim 6, further comprising:
providing a mask over the gate structure and the second doping region; and
forming a third doping region within the first doping region and extending away from a bottom surface of the first doping region.

9. The method of claim 8, wherein a width of the first doping region is greater than the width of the third doping region.

10. The method of claim 6, wherein a width of the first spacer is less than a width of the second spacer.

11. A semiconductor structure, comprising:
a substrate having a top surface and a bottom surface opposite the top surface;
a gate structure disposed on the top surface of the substrate; and
a first source/drain region and a second source/drain region formed below the top surface of the substrate;
wherein a cross sectional area of the first source/drain region is greater than a cross sectional area of second source/drain region.

12. The structure of claim 11, wherein the first source/drain region includes a first doping region and a third doping region, and the second source/drain region includes a second doping region.

13. The structure of claim 12, wherein a width of the first doping region is greater than the width of the third doping region.

14. The structure of claim 11, further comprises:
a first spacer and a second spacer corresponding disposed on sidewalls of the gate structure;
wherein a width of the first spacer is less than a width of the second spacer.

15. The structure of claim 14, wherein the first source/drain region includes a first doping region and a first lightly doped region, and the second source/drain region includes a second doping region and a second lightly doped region.

16. The structure of claim 15, wherein a width of the first lightly doped region is less than a width of the second lightly doped region.

17. The structure of claim 16, wherein a width of the first lightly doped region is greater than a width of the first doping region; and wherein a width of the second lightly doped region is greater than a width of the second doping region.

18. The structure of claim 15, wherein the first source/drain region further includes a third doping region formed within the first doping region and extending away from a bottom surface of the first doping region.

19. The structure of claim 1, wherein a total volume of the first source/drain region is greater than a total volume of the second source/drain region.

20. The structure of claim 1, wherein the gate structure comprises:
an oxide layer disposed on the top surface of the substrate; and
a gate electrode disposed on the oxide layer.
